(19) United States
(12) Patent Application Publication
(10) Pub. No.: US 2025/0389801 A1
(43) Pub. Date: Dec. 25, 2025

(54) SPECTRUM GENERATION APPARATUS AND MAGNETIC RESONANCE IMAGING APPARATUS

(71) Applicant: Canon Medical Systems Corporation, Otawara-shi (JP)

(72) Inventors: Shuki MARUYAMA, Nasushiobara (JP); Hidenori TAKESHIMA, Tokyo (JP)

(73) Assignee: Canon Medical Systems Corporation, Otawara-shi (JP)

(21) Appl. No.: 19/244,185

(22) Filed: Jun. 20, 2025

(30) Foreign Application Priority Data
Jun. 20, 2024 (JP) 2024-099889
May 13, 2025 (JP) 2025-080700

(51) Int. Cl. G01R 33/56; G01R 33/54

(52) U.S. Cl. CPC G01R 33/5608; G01R 33/543

(57) ABSTRACT

According to one embodiment, a spectrum generation apparatus executing: acquiring, for each of a plurality of voxels included in a VOI, a parameter value of one or more kinds of morphological correlation parameters correlated to a morphology in the VOI; estimating, for each of the voxels, a parameter value of one or more spectrum generation parameters based on the parameter value of the morphological correlation parameter; and applying the parameter value of the one or more spectrum generation parameters of each of the voxels to a basis spectrum to generate a plurality of first artificial spectra corresponding to the voxels and generate a second artificial spectrum corresponding to the VOI based on the first artificial spectra.

### CROSS-REFERENCE TO RELATED APPLICATION

This application is based upon and claims the benefit of priority from Japanese Patent Application No. 2024-099889, filed Jun. 20, 2024; and No. 2025-080700, filed May 13, 2025; the entire contents of all of which are incorporated herein by reference.

### FIELD

Embodiments described herein relate generally to a spectrum generation apparatus and a magnetic resonance imaging apparatus

### BACKGROUND

A magnetic resonance spectroscopy (MRS) acquires an average spectrum in a volume of interest. On the other hand, there is a technique of artificially generating a spectrum by MRS in a volume of interest using simulation. However, it is difficult for the artificial spectrum to completely reproduce a measured spectrum, and there is a gap between the artificial spectrum and the measured spectrum.

### BRIEF DESCRIPTION OF DRAWINGS

FIG. 1 is a diagram illustrating a configuration example of a magnetic resonance imaging apparatus according to the present embodiment.

FIG. 2 is a diagram illustrating an example of artificial spectrum generation processing by the magnetic resonance imaging apparatus illustrated in FIG. 1.

FIG. 3 is a diagram schematically illustrating artificial spectrum generation processing illustrated in FIG. 2.

FIG. 4 is a diagram illustrating mathematical expression of a spectrum signal model Y(ν).

FIG. 5 is a view illustrating a first display screen of a second artificial spectrum.

FIG. 6 is a view illustrating a second display screen of a second artificial spectrum.

FIG. 7 is a diagram illustrating an input/output relationship of a parameter estimation model.

FIG. 8 is a diagram schematically illustrating processing of generating a parameter estimation model.

FIG. 9 is a diagram illustrating an input/output relationship of a parameter estimation model according to a first specific example.

FIG. 10 is a diagram illustrating an input/output relationship of a parameter estimation model according to a second specific example.

FIG. 11 is a diagram illustrating an input/output relationship of a parameter estimation model according to a third specific example.

FIG. 12 is a diagram illustrating an input/output relationship of a parameter estimation model according to a fourth specific example.

FIG. 13 is a diagram illustrating an input/output relationship of a trained model according to a fifth specific example.

FIG. 14 is a diagram schematically illustrating a first stage of training processing of a trained model #1 and a trained model #2 illustrated in FIG. 13.

FIG. 15 is a diagram schematically illustrating a second stage of the training processing of the trained model #1 and the trained model #2 illustrated in FIG. 13.

FIG. 16 is a diagram illustrating an input/output relationship of a trained model according to a sixth specific example.

FIG. 17 is a diagram illustrating a configuration example of a spectrum generation apparatus according to a first modification.

### DETAILED DESCRIPTION

A spectrum generation apparatus according to an embodiment includes an acquisition unit, an estimation unit, and a generation unit. The acquisition unit acquires, for each of a plurality of voxels included in the volume of interest, parameter values of one or more morphological correlation parameters correlated with a morphology in the volume of interest. The estimation unit estimates, for each of the plurality of voxels, parameter values of one or more kinds of spectrum generation parameters based on the parameter values of the morphological correlation parameters. The generation unit generates a plurality of first artificial spectra corresponding to the plurality of voxels by applying parameter values of the one or more kinds of spectrum generation parameters of each of the plurality of voxels to a basis spectrum, and generates a second artificial spectrum corresponding to the volume of interest based on the plurality of first artificial spectra.

Hereinafter, a spectrum generation apparatus and a magnetic resonance imaging apparatus according to the present embodiment will be described in detail with reference to the drawings.

The spectrum generation apparatus according to the present embodiment is a computer that artificially generates various spectra that can be collected by a magnetic resonance imaging apparatus. The spectrum according to the present embodiment means digital data representing a frequency distribution of a signal intensity value of a magnetic resonance signal. The spectrum generation apparatus may be a computer incorporated in the magnetic resonance imaging apparatus, or may be a computer separate from the magnetic resonance imaging apparatus. In the following embodiments, it is assumed that the spectrum generation apparatus is incorporated in a magnetic resonance imaging apparatus.

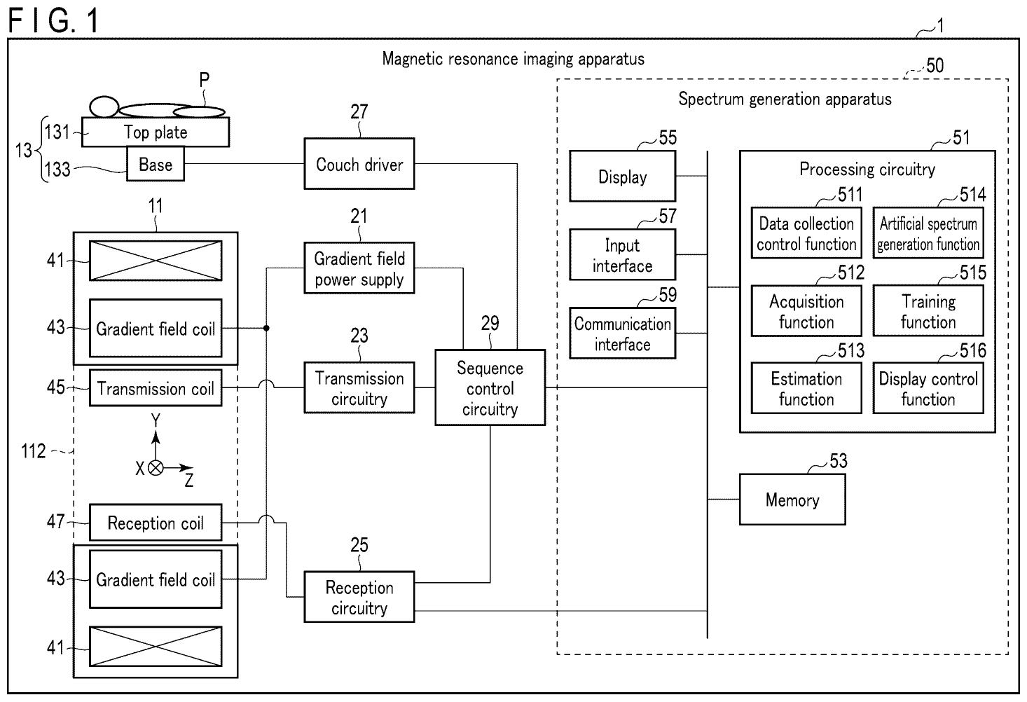

FIG. 1 is a diagram illustrating a configuration example of a magnetic resonance imaging apparatus 1 according to a first embodiment. As illustrated in FIG. 1, the magnetic resonance imaging apparatus 1 includes a gantry 11, a couch 13, a gradient field power supply 21, a transmission circuitry 23, a reception circuitry 25, a couch driver 27, a sequence control circuitry 29, and a spectrum generation apparatus (host computer) 50.

The gantry 11 includes a static field magnet 41 and a gradient field coil 43. The static field magnet 41 and the gradient field coil 43 are accommodated in a housing of the gantry 11. A bore having a hollow shape is formed in the housing of the gantry 11. The transmission coil 45 and the reception coil 47 are arranged in the bore of the gantry 11.

The static field magnet 41 has a hollow substantially cylindrical shape and generates a static magnetic field inside the substantially cylindrical shape. As the static field magnet 41, for example, a permanent magnet, a superconducting magnet, a normal conducting magnet, or the like is used. Here, a central axis of the static field magnet 41 is defined as a Z axis, an axis vertically orthogonal to the Z axis is defined as a Y axis, and an axis horizontally orthogonal to the Z axis is defined as an X axis. The X axis, the Y axis, and the Z axis configure an orthogonal three-dimensional coordinate system.

The gradient field coil 43 is a coil unit attached to the inside of the static field magnet 41 and formed in a hollow substantially cylindrical shape. The gradient field coil 43 generates a gradient magnetic field by receiving supply of a current from the gradient field power supply 21. More specifically, the gradient field coil 43 has three coils corresponding to the X axis, the Y axis, and the Z axis orthogonal to each other. The three coils form a gradient magnetic field in which the magnetic field intensity changes along each of the X axis, the Y axis, and the Z axis. The gradient magnetic fields along the X axis, the Y axis, and the Z axis are merged, and a slice selection gradient magnetic field Gs, a phase encoding gradient magnetic field Gp, and a frequency encoding gradient magnetic field Gr orthogonal to each other are formed in a desired direction. The slice selection gradient magnetic field Gs is arbitrarily used to determine an imaging cross-section (slice). The phase encoding gradient magnetic field Gp is utilized to change the phase of the magnetic resonance signal (hereinafter, referred to as an MR signal) depending on a spatial position. The frequency encoding gradient magnetic field Gr is utilized to vary the frequency of the MR signal depending on the spatial position. In the following description, it is assumed that a tilt direction of the slice selection gradient magnetic field Gs is the Z axis, a tilt direction of the phase encoding gradient magnetic field Gp is the Y axis, and a tilt direction of the frequency encoding gradient magnetic field Gr is the X axis.

The gradient field power supply 21 supplies a current to the gradient field coil 43 according to a sequence control signal from the sequence control circuitry 29. The gradient field power supply 21 supplies a current to the gradient field coil 43 to cause the gradient field coil 43 to generate a gradient magnetic field along each of the X axis, the Y axis, and the Z axis. The gradient magnetic field is superimposed on a static magnetic field formed by the static field magnet 41 and applied to a subject P.

The transmission coil 45 is disposed, for example, inside the gradient field coil 43, and generates a high-frequency pulse (hereinafter, referred to as an RF pulse) by receiving supply of a current from the transmission circuitry 23.

The transmission circuitry 23 supplies a current to the transmission coil 45 in order to apply an RF pulse for exciting a target proton such as a hydrogen atom nucleus present in the subject P to the subject P via the transmission coil 45. The RF pulse oscillates at a resonance frequency unique to the target proton to excite the target proton. An MR signal is generated from the excited target proton and detected by the reception coil 47. The transmission coil 45 is, for example, a whole-body coil (WB coil). The whole-body coil may be used as a transmission/reception coil.

The reception coil 47 receives the MR signal emitted from the target proton existing in the subject P under the action of the RF pulse. The reception coil 47 includes a plurality of reception coil elements capable of receiving an MR signal. The received MR signal is supplied to the reception circuitry 25 in a wired or wireless manner. Although not illustrated in FIG. 1, the reception coil 47 has a plurality of reception channels implemented in parallel. The reception channel includes a reception coil element that receives the MR signal, an amplifier that amplifies the MR signal, and the like. The MR signal is output for each reception channel. The total number of receiving channels and the total number of reception coil elements may be the same, or the total number of receiving channels may be larger or smaller than the total number of reception coil elements.

The reception circuitry 25 receives the MR signal generated from the excited target proton via the reception coil 47. The reception circuitry 25 performs signal processing on the received MR signal to generate a digital MR signal. The digital MR signal can be represented in a k-space defined by a spatial frequency. Therefore, hereinafter, the digital MR signal is referred to as k-space data. The k-space data is supplied to the host computer 50 in a wired or wireless manner.

Note that the transmission coil 45 and the reception coil 47 described above are merely examples. Instead of the transmission coil 45 and the reception coil 47, a transmission/reception coil having a transmission function and a reception function may be used. In addition, the transmission coil 45, the reception coil 47, and the transmission/reception coil may be combined.

A couch 13 is installed adjacent to the gantry 11. The couch 13 has a top plate 131 and a base 133. The subject P is placed on the top plate 131. The base 133 slidably supports the top plate 131 along each of the X axis, the Y axis, and the Z axis. The couch driver 27 is accommodated in the base 133. The couch driver 27 moves the top plate 131 under the control of the sequence control circuitry 29. The couch driver 27 may include, for example, any motor such as a servo motor or a stepping motor.

The sequence control circuitry 29 includes, as hardware resources, a processor of a central processing unit (CPU) or a micro processing unit (MPU), and a memory such as a read only memory (ROM) or a random access memory (RAN). The sequence control circuitry 29 synchronously controls the gradient field power supply 21, the transmission circuitry 23, and the reception circuitry 25 based on the data collection condition set by the processing circuitry 51, performs data collection according to the data collection condition on the subject P. and collects k-space data related to the subject P.

The sequence control circuitry 29 according to the present embodiment can also execute MRS imaging, which is a type of spectrum collection. MRS imaging is an imaging method for measuring a chemical shift, which is a minute difference in resonance frequency of a target proton, occurring according to a difference in chemical environment. MRS imaging includes a single voxel method of collecting data for a single voxel and a multi-voxel method of collecting data for a plurality of voxels, and the present embodiment is applicable to any method. The multi-voxel method is also called chemical shift imaging (CSI), magnetic resonance spectroscopic imaging (MRSI), or the like. A spatial region to be measured is referred to as a volume of interest. The volume of interest means a spatial region configured by a plurality of voxels.

When the sequence control circuitry 29 executes MRS imaging, a free induction decay (FID) signal or a spin echo signal is generated from the volume of interest set in the subject P. The reception circuitry 25 receives the FID signal or the spin echo signal via the reception coil 47, and performs signal processing on the received FID signal or spin echo signal to collect k-space data. It is assumed that the collected k-space data is digital data representing a signal strength value emitted from the volume of interest in a time function. The pulse sequence of MRS imaging is repeated by the number of excitation (NEX), and k-space data corresponding to the number of excitation is collected.

As illustrated in FIG. 1, the spectrum generation apparatus 50 is a computer including a processing circuitry 51, a memory 53, a display 55, an input interface 57, and a communication interface 59.

The processing circuitry 51 includes a processor such as a CPU as a hardware resource. The processing circuitry 51 functions as a center of the magnetic resonance imaging apparatus 1. For example, the processing circuitry 51 implements a data collection control function 511, an acquisition function 512, an estimation function 513, an artificial spectrum generation function 514, a training function 515, and a display control function 516 by executing various programs.

By the data collection control function 511, the processing circuitry 51 controls the sequence control circuitry 29 to perform various data collection on the subject P, and collects k-space data via the reception circuitry 25. As a type of data collection, main imaging, calibration imaging, spectrum collection, and the like are possible. This imaging collects T1-weighted images, T2-weighted images, and other MRI images. Calibration imaging occurs prior to this imaging to collect a shimming map representing the spatial distribution of the magnetic field inhomogeneity. As the spectrum collection, MRS imaging for collecting MRS spectra is used. The processing circuitry 51 can also generate various images and spectra based on the collected k-space data.

By means of the acquisition function 512, the processing circuitry 51 acquires, for each of the plurality of voxels included in the volume of interest, parameter values of one or more morphological correlation parameters correlated to a morphology in the volume of interest. The morphology correlation parameter includes a morphological image representing a morphology within the volume of interest and/or a label for an anatomical site corresponding to the morphology within the volume of interest. The morphological image includes a collected image collected by the sequence control circuitry 29, a segmentation image obtained by performing segmentation processing on the collected image, and/or a quantitative value map generated based on the collected image. The collected images include MRI images collected by the present imaging and/or shimming data collected by the calibration imaging. As the shimming data, a shimming map representing the spatial distribution of the magnetic field inhomogeneity and a BC map representing the spatial distribution of the static magnetic field intensity may be used. As an example, the processing circuitry 51 may obtain a measured spectrum of metabolites in the volume of interest collected by spectral imaging.

The processing circuitry 51 may generate the parameter value of the morphological correlation parameter described above, or may receive the parameter value from another computer or the like. For example, the processing circuitry 51 can generate the MRI image, the shimming map, and the measured spectrum based on the k-space data collected by the data collection control function 511. As another example, the processing circuitry 51 can generate the segmentation image and the quantitative value map based on the MRI image generated as described above.

By means of the estimation function 513, the processing circuitry 51 estimates a plurality of parameter sets corresponding to a plurality of voxels based on the parameter values of the morphological correlation parameters acquired by the acquisition function 512. Each of the plurality of parameter sets includes a parameter value of one or more kinds of spectrum generation parameters.

By the artificial spectrum generation function 514, the processing circuitry 51 applies the plurality of parameter sets estimated by the estimation function 513 to the basis spectrum to generate a plurality of first artificial spectra corresponding to the plurality of voxels included in the volume of interest. Then, the processing circuitry 51 generates a second artificial spectrum corresponding to the volume of interest based on the plurality of first artificial spectra.

With the training function 515, the processing circuitry 51 trains an unlearned machine training-in-Progress model based on a plurality of training samples to generate a trained model to be used in the estimation function 513.

By the display control function 516, the processing circuitry 51 displays various types of information on the display 55. For example, the processing circuitry 51 displays the second artificial spectrum generated by the artificial spectrum generation function 514 on the display 55.

The memory 53 is a memory device such as a hard disk drive (HDD), a solid state drive (SSD), or an integrated circuit memory device that stores various types of information. Furthermore, the memory 53 may be a drive device or the like that reads and writes various types of information from and to a portable storage medium such as a CD-ROM drive, a DVD drive, or a flash memory.

The display 55 displays various types of information by the display control function 516. As the display 55, for example, a CRT display, a liquid crystal display, an organic EL display, an LED display, a plasma display, or any other display known in the art can be appropriately used.

The input interface 57 includes an input device that receives various commands from the user. As the input device, a keyboard, a mouse, various switches, a touch screen, a touch pad, and the like can be used. Note that the input device is not limited to a device including physical operation components such as a mouse and a keyboard. For example, an electric signal processing circuitry that receives an electric signal corresponding to an input operation from an external input device provided separately from the magnetic resonance imaging apparatus 1 and outputs the received electric signal to various circuits is also included in the example of the input interface 57. Furthermore, the input interface 57 may be a voice recognition device that converts a voice signal collected by a microphone into an instruction signal.

The communication interface 59 is an interface that connects the magnetic resonance imaging apparatus 1 to a workstation, a picture archiving and communication system (PACS), a hospital information system (HIS), a radiology information system (RIS), or the like via a local area network (LAN) or the like.

The network IF transmits and receives various types of information to and from a workstation, a PACS, a HIS, and a RIS that are connection destinations.

Hereinafter, the artificial spectrum generation processing by the magnetic resonance imaging apparatus 1 will be described in detail.

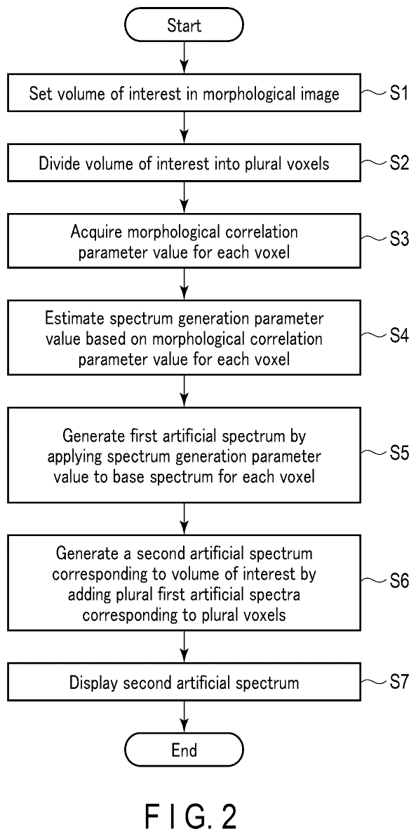

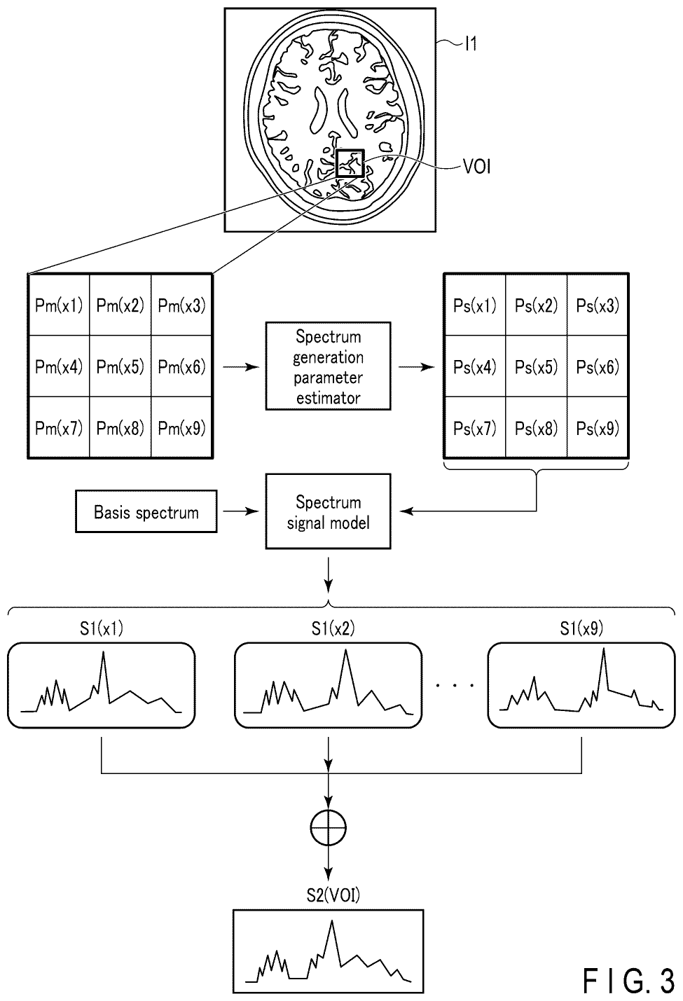

FIG. 2 is a diagram illustrating an example of artificial spectrum generation processing by the magnetic resonance imaging apparatus 1. FIG. 3 is a diagram schematically illustrating artificial spectrum generation processing in FIG. 2.

First, in step S1, the processing circuitry 51 sets the volume of interest VOI in the morphological image I1 by realizing the acquisition function 512 (step S1). The morphological image I1 is a T1-weighted image, a T2-weighted image, a FLAIR image, or other MRI images representing the internal morphology of the subject P collected by performing MR imaging on the subject P. In other words, the morphological image I1 is a spatial distribution of parameter values of morphological correlation parameters, and a parameter value of a morphological correlation parameter is assigned to each pixel of the morphological image I1. It is assumed that the morphological image I1 is generated by the processing circuitry 51 in advance before step S1.

The morphological image I1 is displayed on the display 55 by the display control function 516 of the processing circuitry 51, and the volume of interest VOI is set in a desired spatial region indicated by the user via the input interface 57. The volume of interest VOI means a spatial region of a generation target of the second artificial spectrum. The volume of interest VOI is preferably set to be larger than an area of one pixel of the morphological image I1.

The morphological image I1 illustrated in FIG. 3 is a head image representing a head of the subject P, and the volume of interest VOI is set in a brain region of the head. However, the present embodiment is not limited thereto, and the volume of interest VOI may be set in any anatomical site such as the heart, the liver, the breast, the prostate, and the muscle fibers. In addition, the shape of the volume of interest VOI is not limited to a square, and may be a rectangle such as a rectangle or a shape obtained by combining rectangles of arbitrary shapes. In the following description, it is assumed that the shape of the volume of interest VOI is a square.

When step S1 is performed, the processing circuitry 51 sets the volume of interest VOI set in step S1 to a plurality of voxels xn (n is a suffix indicating a number of a voxel) by realizing the acquisition function 512. 1≤n≤N. N is the number of voxels included in the volume of interest VOI (step S2). The voxel xn has a size corresponding to the spatial resolution of the morphological image I1, and is typically smaller than the size of the volume of interest VOI. In FIG. 3, as an example, the volume of interest VOI is divided into nine (N=9) voxels xn. In other words, the morphological image I1 is an image collected with spatial resolution corresponding to N voxels, which is higher than the spatial resolution corresponding to the volume of interest VOI.

When step S2 is performed, the processing circuitry 51 acquires a parameter value Pm(xn) of a morphological correlation parameter Pm for each of the plurality of voxels xn divided in step S2 by realizing the acquisition function 512 (step S3). Specifically, the processing circuitry 51 reads the parameter value Pm(xn) of the morphological correlation parameter Pm from each voxel xn of the volume of interest VOI from the morphological image I1. Hereinafter, the parameter value of the morphological correlation parameter is referred to as a morphological correlation parameter value.

When step S3 is performed, the processing circuitry 51 estimates a parameter value Ps(xn) of a spectrum generation parameter Ps based on a morphological correlation parameter value Pm(xn) acquired in step S3 for each of the plurality of voxels xn by realizing the estimation function 513 (step S4). The spectrum generation parameter Ps is a generic term for one or more types of parameters configuring a spectrum signal model. Here, the spectrum signal model means a mathematical model representing a basis spectrum with the spectrum generation parameter Ps. Specifically, the spectrum generation parameter Ps includes a baseline with respect to the basis spectrum, a phase shift with respect to the basis spectrum, a concentration of a metabolite represented by the basis spectrum, a half-value width of the basis spectrum, and/or a frequency shift with respect to the basis spectrum. In step S4, the processing circuitry 51 applies the parameter value Pm(xn) to the trained model or the random number generator to estimate the parameter value Ps(xn). The trained model and the random number generator are collectively referred to as a spectrum generation parameter estimator. Hereinafter, the parameter value of the spectrum generation parameter is referred to as a spectrum generation parameter value.

When step S4 is performed, the processing circuitry 51 generates the first artificial spectrum S1(xn) by applying the spectrum generation parameter value Ps(xn) estimated in step S4 to the base spectrum for each of the plurality of voxels xn by realizing the artificial spectrum generation function 514 (step S5). The first artificial spectrum S1(xn) is mathematically represented by a spectral signal model. As described above, the spectrum signal model is a mathematical model representing the base spectrum with the spectrum generation parameter Ps.

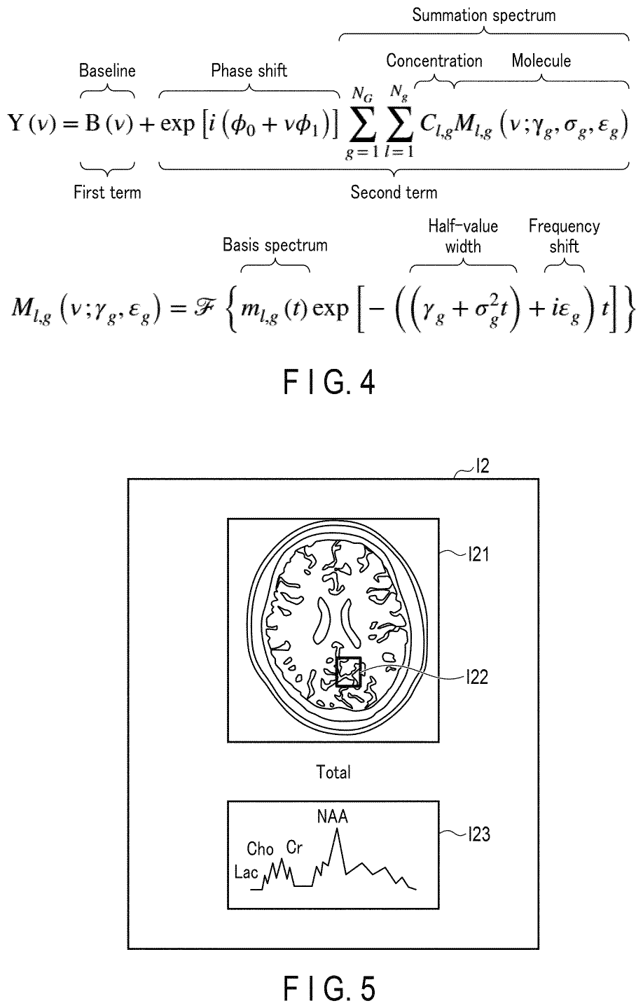

FIG. 4 is a diagram illustrating a mathematical expression of the spectrum signal model Y(ν). As illustrated in FIG. 4, the spectral signal model Y(ν) is represented by the sum of the first term and the second term. The first term represents the baseline B(ν) of the first artificial spectrum. The second term represents a summation spectrum to which the phase shift exp [i(φ₀+νφ₁)] is applied. The summation spectrum represents the sum of artificial spectra for each metabolite 1 and metabolite group g. Each metabolite 1 belongs to any one group g. In the following embodiments, it is assumed that all metabolites 1 are aggregated into one group g, i.e. g=1. For example, all metabolites such as NAA and Cho are assigned to one group. The metabolite 1 may represent a metabolite or may represent a class of metabolites having similar structures. The artificial spectrum for each of the metabolite 1 and the group g is represented by the product of the concentration C_{l, g} and the molecular term M_{l, g} of the metabolite 1 and the group g. The molecular term M_{l, g} is represented by the inverse Fourier transform of the base spectrum m_{l, g} to which the half-value width (γ_{g}+σ_{g}²) and the frequency shift ε_{g} are applied.

The spectrum signal model Y(ν) illustrated in FIG. 4 includes a phase shift exp [i(φ₀+νφ₁)], a concentration C_{l, g}, a basis spectrum m_{l, g}, a half-value width (γ_{g}+σ_{g}²), and a frequency shift ε_{g} as the spectrum generation parameter Ps. The half-value width is assumed to be a full width at half maximum (FWHM), but is not limited thereto, and may be any index representing the degree of the width of the peak of the spectrum such as a half width at half maximum (HWHM). ν means frequency. Each metabolite l may be distributed to a plurality of metabolite groups g. For example, Glx, Glu, and GABA may be allocated to the first group, and other metabolites may be allocated to the second group. In this case, g=2. By distributing the metabolite l into a plurality of groups g, the spectrum generation parameter value Ps (xn) can be estimated more flexibly.

An example of a method for generating the first artificial spectrum using the spectrum signal model Y(ν) will be described. The human tissue has a combination of metabolites according to the type of the tissue, and a combination of spectrum generation parameter values Ps(xn) differs according to the type of the metabolites. The memory 53 stores a first look up table (LUT) associating a type of human tissue with a metabolite group included in the human tissue, and a second LUT associating a combination of spectrum generation parameter values Ps(xn) for each metabolite group. In the second LUT, a parameter value Ps(xn) is registered for each of a plurality of metabolites belonging to each group. It is assumed that the first LUT and the second LUT are generated in advance based on data obtained by actually measured spectrum collection, data obtained by simulation, and the like. In addition, the memory 53 stores the basal spectra m_{l,g} for each combination of metabolites and metabolite groups. The base spectra mi, g are obtained by simulation or by actually measured spectral collection on a phantom.

The processing circuitry 51 specifies the type of the human tissue in which the volume of interest VOI is set. The type of the human tissue may be specified by image processing using registration for each corresponding reference point between the morphological image and the human atlas, or may be artificially designated via the input interface 57. The processing circuitry 51 inputs the identified type of human tissue to the first LUT, identifies the type of metabolite group associated with the type, inputs the identified type to the second LUT, and identifies a combination of parameter values Ps(xn) of the spectrum generation parameters Ps associated with the type. In addition, the processing circuitry 51 reads the basal spectra m_{l,g} for each metabolite included in the identified type from the memory 53.

The processing circuitry 51 generates the first artificial spectrum S1(xn) by applying the combination of the specified parameter values Ps(xn) and the basis spectra m_{l,g} to the spectrum signal model Y(ν) illustrated in FIG. 4, adding the artificial spectrum (second term) over all the metabolites included in all the voxels xn, and adding the baseline B(ν) to the addition result. As a result, the first artificial spectrum as the sum of the artificial spectra corresponding to all the metabolites included in each voxel xn is generated. For example, as illustrated in FIG. 3, when the number of voxels xn is nine (N=9), nine first artificial spectra S1(x1) to S1(x9) are generated.

As the first artificial spectrum S1(xn), not only the sum of the artificial spectra of all metabolites included in each voxel xn but also the artificial spectrum of each metabolite may be generated. Hereinafter, when both are distinguished, a first artificial spectrum obtained by summing all artificial spectra corresponding to all metabolites is referred to as a first synthetic artificial spectrum, and a first artificial spectrum corresponding to each metabolite is referred to as a first individual artificial spectrum.

When step S5 is performed, the processing circuitry 51 adds the plurality of first artificial spectra S1(xn) corresponding to the plurality of voxels xn generated in step S5 by realizing the artificial spectrum generation function 514 to generate the second artificial spectrum S2(VOI) corresponding to the volume of interest VOI (step S6). For example, as illustrated in FIG. 3, when the number of voxels xn is nine (N=9), nine first artificial spectra S1(x1) to S1(x9) are generated. As described above, it is possible to generate one second artificial spectrum S2(VOI) corresponding to the volume of interest VOI by generating a plurality of first artificial spectra S1(xn) respectively corresponding to a plurality of voxels xn and adding the plurality of first artificial spectra S1(xn). Since the spectrum is collected in the volume of interest VOI unit instead of the voxel xn unit in the actual spectrum collection, the second artificial spectrum S2(VOI) is expected to be closer in accuracy to the actually collected spectrum than the first artificial spectrum S1.

As the second artificial spectrum S2(VOI), the second individual artificial spectrum may be generated in addition to the second synthetic artificial spectrum. The second synthetic artificial spectrum can be generated by adding the plurality of first synthetic artificial spectra corresponding to the plurality of voxels xn included in the volume of interest. The second individual artificial spectrum can be generated by adding the plurality of first individual artificial spectra corresponding to the plurality of voxels xn included in the volume of interest.

When step S6 is performed, the processing circuitry 51 displays the second artificial spectrum S2(VOI) generated in step S6 by realizing the display control function 516 (step S7). As an example, the processing circuitry 51 displays the second artificial spectrum S2(VOI) on the display 55 in a predetermined layout.

FIG. 5 shows a first display screen I2 of the second artificial spectrum S2(VOI). The display screen I2 is displayed on the display 55 by the processing circuitry 51. As illustrated in FIG. 5, a morphological image 121 is displayed on the display screen I2, and a mark I22 representing the volume of interest set in step S1 is superimposed on the morphological image 121. The second synthetic artificial spectrum 123 corresponding to the volume of interest indicated by the mark I22 generated in step S6 is further displayed on the display screen I2. A character string representing the name or symbol of the corresponding metabolite may be attached to each peak of the second synthetic artificial spectrum 123. For example, as illustrated in FIG. 5, in a case where the volume of interest is set to the brain gray matter, since the volume of interest includes metabolites such as Lac, Cho, Cr, and NAA, a character string of “Lac”, “Cho”, “Cr”, or “NAA” may be displayed side by side at each peak of the second synthetic artificial spectrum 123.

The display of the second synthetic artificial spectrum 123 allows the user to see the spectrum that can be collected at the volume of interest before the spectrum collection is actually performed.

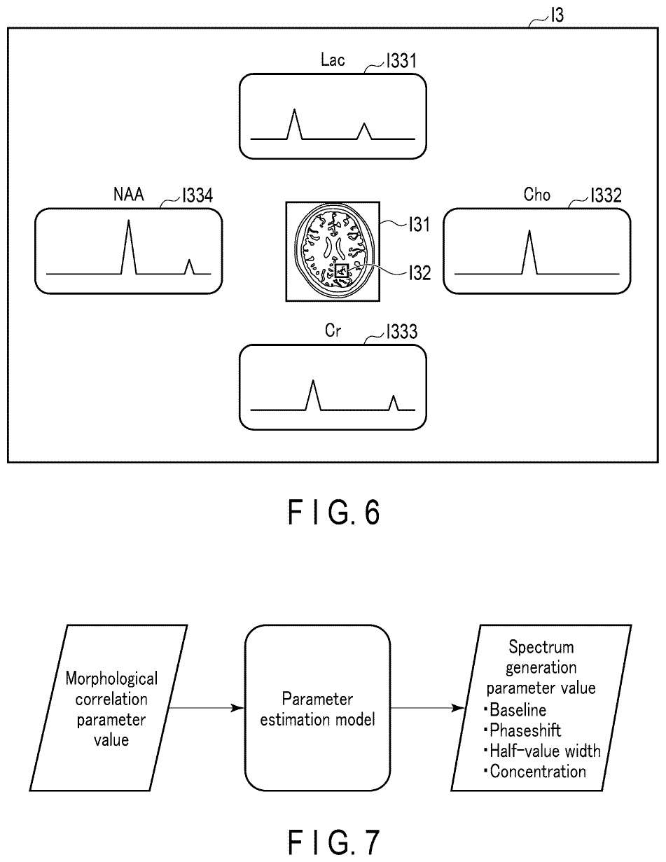

FIG. 6 is a diagram showing a second display screen I3 of the second artificial spectrum S2 (VOI). The display screen I3 is displayed on the display 55 by the processing circuitry 51. As illustrated in FIG. 6, a morphological image 131 is displayed on the display screen I3, and a mark I32 representing the volume of interest set in step S1 is superimposed on the morphological image 131. The display screen I3 further displays a second individual artificial spectrum I33m (m is an index of the second individual artificial spectrum) corresponding to the volume of interest indicated by the mark I32, generated in step S6. 1≤m≤M. M is the number of second individual artificial spectra). More specifically, M second individual artificial spectra I33m corresponding to M metabolites that may be included in the volume of interest are displayed as the second individual artificial spectrum I33m. A second individual artificial spectrum I33m is arranged around the morphological image 131.

For example, as illustrated in FIG. 6, in a case where the volume of interest is set to the brain gray matter, a spectrum 1331 corresponding to Lac, a spectrum 1332 corresponding to Cho, a spectrum 1333 corresponding to Cr, and a spectrum 1334 corresponding to NAA are arranged in such a way as to surround the morphological image 131. By displaying the second individual artificial spectrum I33m, the user can confirm metabolites that can be included in the volume of interest and individual spectra of the metabolites.

The processing circuitry 51 may switch between the display of the second synthetic artificial spectrum illustrated in FIG. 5 and the display of the second individual artificial spectrum illustrated in FIG. 6 in accordance with a switching instruction from the user via the input interface 57.

When step S7 is performed, the artificial spectrum generation processing by the magnetic resonance imaging apparatus 1 ends.

As described above, according to the artificial spectrum generation processing illustrated in FIG. 2, it is possible to accurately generate the second artificial spectrum expected to be collected for the volume of interest before actually performing the spectrum collection for the volume of interest. Therefore, the user can accurately narrow down the size and/or position of the volume of interest on which the spectrum collection is performed in advance. According to the present embodiment, it is possible to reduce the number of times of spectrum collection until a desired measured spectrum is collected as compared with the comparative example in which the artificial spectrum is not confirmed. In addition, since the processing circuitry 51 generates and displays the second artificial spectrum in response to the user setting the volume of interest in the morphological image, the user can easily confirm the second artificial spectrum with high accuracy.

Next, the trained model used for the estimation of the spectrum generation parameter value in step S4 will be described. Hereinafter, the trained model will be referred to as a parameter estimation model.

FIG. 7 is a diagram illustrating an input/output relationship of a parameter estimation model. As illustrated in FIG. 7, the parameter estimation model is a machine training-in-Progress model that inputs a morphological correlation parameter value and outputs a spectrum generation parameter value. The parameter estimation model assumes a neural network configured by combining a fully connected layer, a convolution layer, a pooling layer, and/or a normalization layer, and other arbitrary network layers. The morphological correlation parameter value may be input as a vector including a plurality of morphological correlation parameter values corresponding to a plurality of voxels included in the volume of interest as an element, or may be input as image data of the volume of interest. The spectrum generation parameter value is output as a vector including a plurality of spectrum generation parameter values corresponding to a plurality of voxels included in the volume of interest in an element. As described above, the spectrum generation parameter value includes a baseline, a phase shift, a half-value width, and/or a concentration in an element.

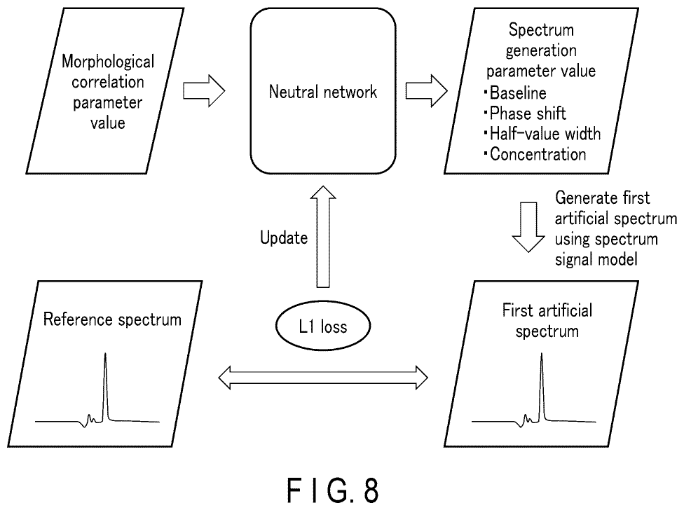

Next, parameter estimation model generation processing by the training function 515 will be described. FIG. 8 is a diagram schematically illustrating processing of generating a parameter estimation model. A neural network illustrated in FIG. 8 means a parameter estimation model of a machine learning target. The processing circuitry 51 trains the neural network based on supervised machine learning based on the plurality of training samples. Each training sample includes an input parameter value and a reference spectrum corresponding to the input parameter value. The reference spectrum is an actually measured spectrum related to the target volume, and is used as correct data. The NEX of the reference spectrum is not particularly limited as long as it is 1 or more, but NEX=1 is assumed. The input parameter value is a parameter value of a morphological correlation parameter related to the target volume, and is used as input data. By performing machine learning based on such a training sample, the neural network can learn a correlation existing between the input parameter value and the reference spectrum.

The processing circuitry 51 inputs the input parameter value to the neural network and performs forward propagation processing based on the input data to calculate a predicted parameter value. The processing circuitry 51 generates a first artificial spectrum from the calculated prediction parameter value using the spectrum signal model. The processing circuitry 51 calculates an L1 loss for evaluating a difference between the generated first artificial spectrum and the reference spectrum, and updates the network parameter of the neural network in such a way as to reduce the calculated L1 loss. The network parameters include weighting factors and biases between network layers. The processing circuitry 51 repeats updating of the network parameters after changing the training sample until a predetermined end condition is satisfied. The network parameter update processing may use any optimization method such as a stochastic gradient descent method or Adam. In a case where the termination condition is satisfied, the network parameter in the number of updates is stored as a learned network parameter. A neural network to which a learned network parameter is assigned is used as a parameter estimation model. The use of a parameter estimation model makes it possible to obtain a spectrum generation parameter value that correlates to a morphological correlation parameter value.

The method of learning the parameter estimation model is not limited to the above-described supervised learning, and may be performed by any method such as unsupervised learning, semi-supervised learning, or self-supervised learning as long as a machine training-in-Progress model that inputs a morphological correlation parameter value and outputs a spectrum generation parameter value can be generated.

Note that the processing circuitry 51 may estimate the spectrum generation parameter value by applying the morphological correlation parameter value to a random number generator. The random number generator means an algorithm that converts the morphological correlation parameter value into a random number. The range of the random number is preferably limited to a possible range of the spectrum generation parameter value. As an example, the processing circuitry 51 sets the morphological correlation parameter value to a seed value, and inputs the seed value to a random number generator to generate a random number. The generated random number is set to the spectrum generation parameter value. In the case of using the random number generator, it is possible to easily obtain the spectrum generation parameter value as compared with the case of using the parameter estimation model.

Next, a specific example of input and output of the parameter estimation model will be described.

### First Specific Example

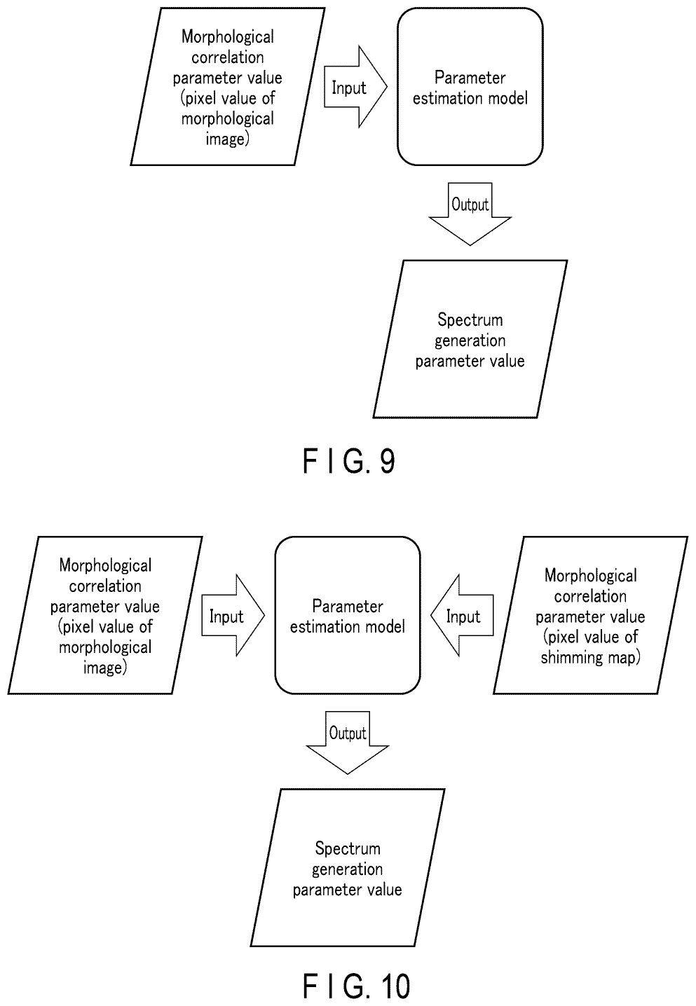

FIG. 9 is a diagram illustrating an input/output relationship of the parameter estimation model according to a first specific example. As illustrated in FIG. 9, one type of morphological correlation parameter value is input and a spectrum generation parameter value is output in a parameter estimation model according to the first specific example. As the morphological correlation parameter value, a pixel value of a morphological image is used.

The morphological image may be an MRI image such as a T1-weighted image or a T2-weighted image collected by the magnetic resonance imaging apparatus 1, or may be a segmentation image generated by performing segmentation processing on the MRI image. For example, in the case of a collected image representing the morphology of the brain of the subject, the collected image is divided into a gray matter image, a white matter image, a cerebrospinal fluid (CSF) image, and other partial images by segmentation processing. In addition, instead of the MRI image, a quantitative value map generated by analyzing the MRI image may be used as the morphological image.

Since a pixel value in the volume of interest in a morphological image may be processed in the parameter estimation model, as an example, the pixel value of the volume of interest in the morphological image may be input to the parameter estimation model. As another example, the pixel value of the entire morphological image may be input to the parameter estimation model. In this case, a network layer that extracts the pixel value in the volume of interest from the pixel value of the morphological image may be provided in the parameter estimation model.

### Second Specific Example

FIG. 10 is a diagram illustrating an input/output relationship of a parameter estimation model according to a second specific example. As illustrated in FIG. 10, two types of morphological correlation parameter values are input and spectrum generation parameter values are output in the parameter estimation model according to the second specific example. As the morphological correlation parameter value, a pixel value of the MRI image and a pixel value of the shimming map are used. Since the shimming map represents the spatial distribution of the magnetic field inhomogeneity, the accuracy of the spectrum generation parameter value is expected to be improved by determining the spectrum generation parameter value in consideration of the pixel value of the shimming map in addition to the pixel value of the MRI image.

As for the shimming map, similarly to the MRI image, the pixel value of the image region corresponding to the volume of interest in the shimming map may be input to the parameter estimation model, or the pixel value of the entire shimming map may be input. Here, in order to match the resolution of the shimming map with the resolution of the MRI image, the processing circuitry 51 may upsample the shimming map and input the shimming map after the upsampling to the parameter estimation model. As another example, a network layer that upsamples the shimming map may be provided in the parameter estimation model. In addition, a quantitative value map may be used instead of the MRI image.

### Third Specific Example

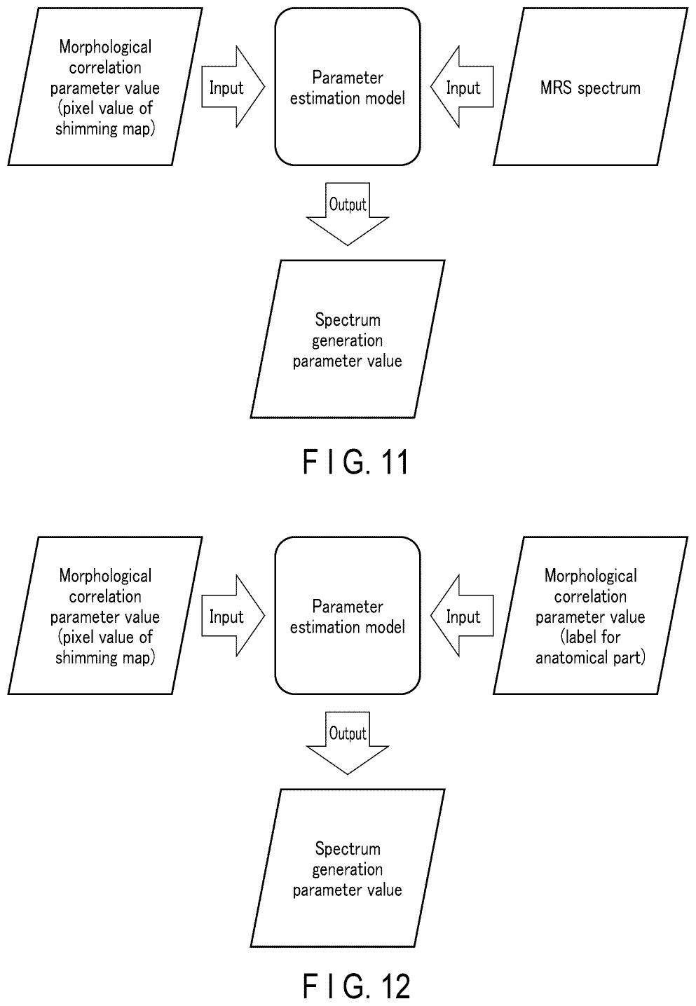

FIG. 11 is a diagram illustrating an input/output relationship of a parameter estimation model according to a third specific example. As illustrated in FIG. 11, one type of morphological correlation parameter value and the MRS spectrum are input and the spectrum generation parameter value is output in the parameter estimation model according to the third specific example. As the morphological correlation parameter value, a pixel value of the shimming map is used. The MRS spectrum is an example of an actually measured spectrum. As the MRS spectrum, a spectrum (actually measured spectrum) actually collected by MRS imaging is used. The measured spectrum is collected by performing MRS imaging in advance at a position same as or close to the volume of interest set in the morphological image. Since the MRS spectrum reflects the composition in the volume of interest, the accuracy of the spectrum generation parameter value is expected to be improved by determining the spectrum generation parameter value in consideration of the MRS spectrum in addition to the pixel value of the morphological image.

The method of inputting the pixel value of the shimming map to the parameter estimation model is similar to that in the second specific example. In addition, upsampling may be performed at any timing similarly to the second specific example. In the third specific example, a collected image or a quantitative value map may be used instead of the shimming map. In addition, the morphological correlation parameter value input to the parameter estimation model is not limited to one type, and may be two or more types as in the first specific example.

### Fourth Specific Example

FIG. 12 is a diagram illustrating an input/output relationship of a parameter estimation model according to a fourth specific example. As illustrated in FIG. 12, two types of morphological correlation parameter values are input and spectrum generation parameter values are output in the parameter estimation model according to the fourth specific example. As the morphological correlation parameter value, a pixel value of a shimming map and a label of an anatomical site are used. The label of the anatomical site means data of a text such as a name or a symbol of the anatomical site in which the volume of interest is set. Since the label of the anatomical site has a value correlated to the morphology in the volume of interest, the accuracy of the spectrum generation parameter value is expected to be improved by determining the spectrum generation parameter value in consideration of the label of the anatomical site in addition to the pixel value of the shimming map.

The method of inputting the pixel value of the shimming map to the parameter estimation model is similar to that in the second specific example. In addition, upsampling may be performed at any timing similarly to the second specific example. In the fourth specific example, a collected image or a quantitative value map may be used instead of the shimming map. In addition, the morphological correlation parameter value input to the parameter estimation model is not limited to one type, and may be two or more types as in the first specific example.

### Fifth Specific Example

A spectrum generation apparatus 50 according to a fifth specific example generates an artificial spectrum of the volume of interest directly from a morphological correlation parameter value for each voxel without passing through the spectrum generation parameter value for each pixel value by using a trained model. This reduces a calculation load for generating an artificial spectrum and improves accuracy of the artificial spectrum.

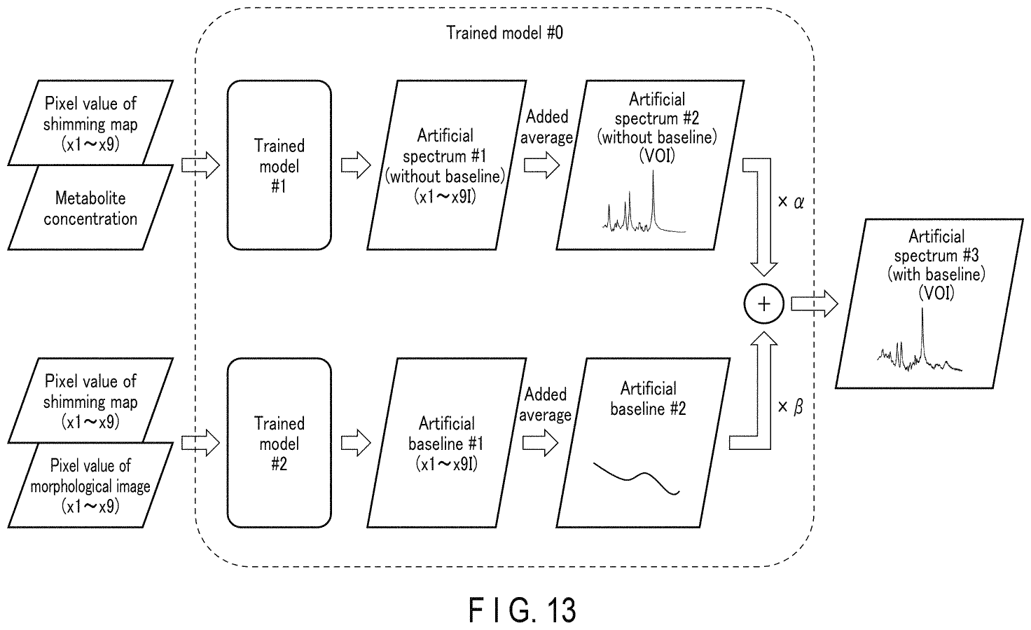

FIG. 13 is a diagram illustrating an input/output relationship of a trained model according to the fifth specific example. Note that, in FIG. 13, the volume of interest VOI is assumed to be, as an example, a rectangular region including nine pixels x1 to x9. Note that the volume of interest VOI according to the fifth specific example can be applied to any size and shape.

As illustrated in FIG. 13, the processing circuitry 51 acquires the morphological image and the shimming map regarding an imaging region including the volume of interest of the subject by the acquisition function 512. As the parameter values of the morphological image and the shimming map, the pixel values of the nine pixels x1 to x9 configuring the volume of interest may be acquired. In addition, by the acquisition function 512, the processing circuitry 51 acquires the concentration (hereinafter, metabolite concentration) of the metabolite that can be included in the volume of interest. The metabolite concentration data can be obtained from various documents such as papers, textbooks, experimental data, and electronic medical charts.

By means of the artificial spectrum generation function 514, the processing circuitry 51 applies the pixel values of the shimming map relating to the volume of interest and the concentration of metabolites that may be included in the volume of interest to the trained model #1 to generate a plurality of artificial spectra #1 corresponding to a plurality of voxels included in the volume of interest. Next, the processing circuitry 51 generates a second artificial spectrum #2 corresponding to the volume of interest based on the plurality of generated first artificial spectra #1. The artificial spectrum #1 has a concentration value (signal intensity value) component, a molecular component, and a phase shift component related to metabolites, but does not include a baseline component. In addition, the processing circuitry 51 applies the pixel value of the shimming map and the pixel value of the morphological image related to the volume of interest to the trained model #2 to generate a plurality of artificial baselines #1 corresponding to a plurality of voxels. The processing circuitry 51 then generates a second artificial baseline #2 corresponding to the volume of interest based on the generated plurality of first artificial baselines #1.

Then, the processing circuitry 51 adds the artificial spectrum #2 and the artificial baseline #2 to generate the artificial spectrum #3 related to the volume of interest. The artificial spectrum #3 includes a baseline component in addition to the concentration value (signal intensity value) component, the molecular component, and the phase shift component related to metabolites illustrated in FIG. 4. Specifically, the processing circuitry 51 performs weighted addition of the artificial spectrum #2 and the artificial baseline #2 to generate the artificial spectrum #3. As an example, the processing circuitry 51 multiplies the artificial spectrum #2 by the weighting coefficient α, multiplies the artificial baseline #2 by the weighting coefficient β, and adds the artificial spectrum #2 with the weighting coefficient α and the artificial baseline #2 with the weighting coefficient β to generate the artificial spectrum #3.

The trained model #1 and the trained model #2 are trained in advance and stored in the memory 53 or the like. The trained model #1 and the trained model #2 may be managed as individual machine training-in-Progress models, or the trained model #1, the trained model #2, and an adder may be collectively managed as one trained model #0. Note that the adder means a network layer that adds the artificial spectrum #2 and the artificial baseline #2.

When expressed as the trained model #0, the processing circuitry 51 applies the parameter value (pixel value) of the shimming map related to the volume of interest, the parameter value (pixel value) of the morphological image related to the volume of interest, and the metabolite concentration that can be included in the volume of interest to the trained model #0 to generate the artificial spectrum #3 related to the volume of interest.

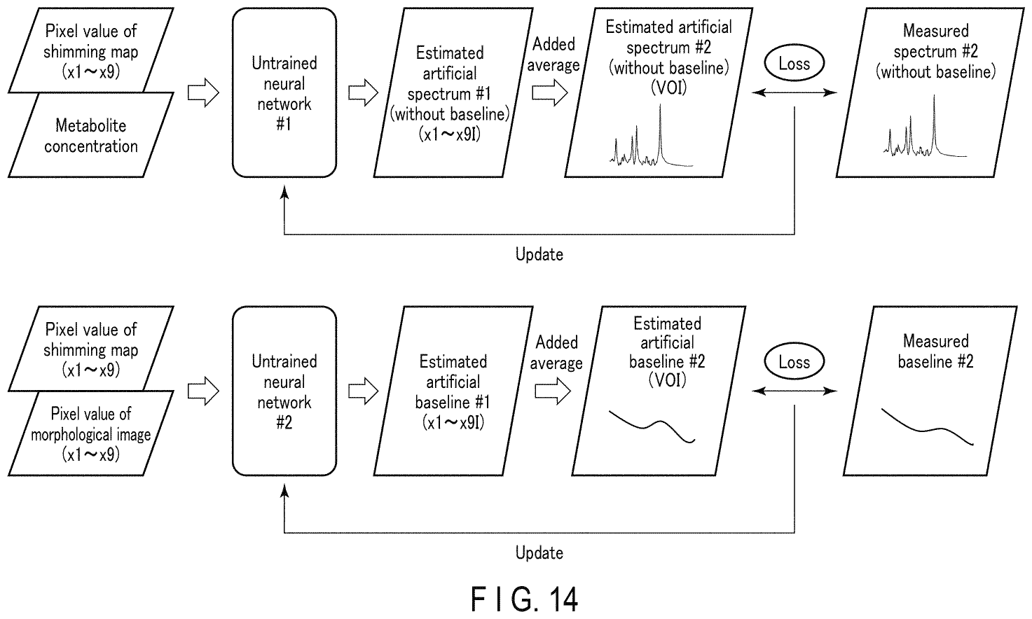

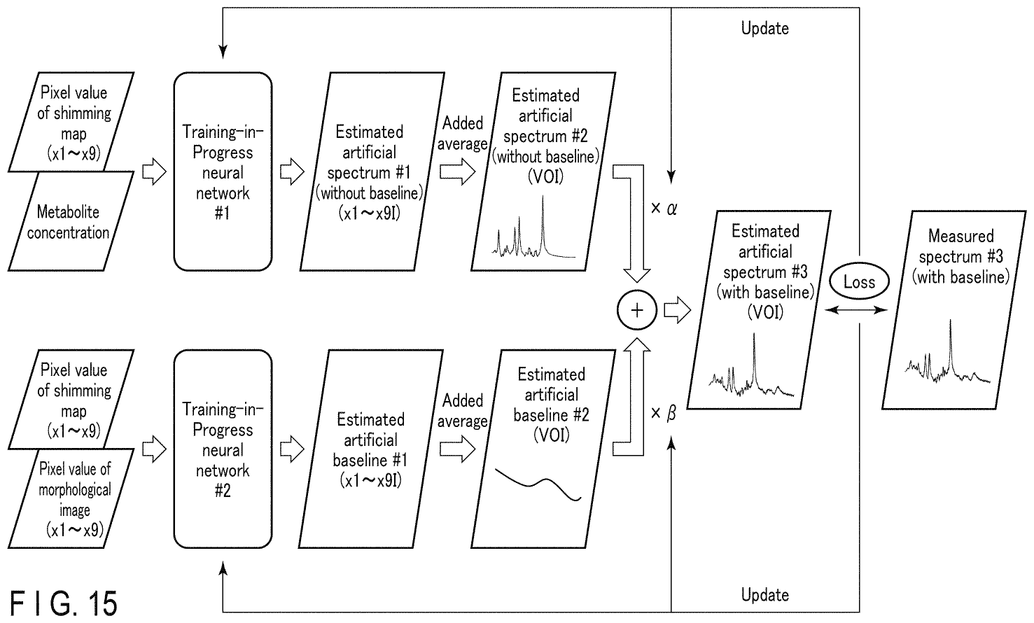

Next, training processing of the trained model #1 and the trained model #2 will be described with reference to FIGS. 14 and 15. The training processing is executed by the training function 515 of the processing circuitry 51. The training processing includes a first stage in which the trained model #1 and the trained model #2 are individually trained, and a second stage in which the trained model #1 and the trained model #2 are collectively fine-tuned.

The trained model #1 and the trained model #2 are generated by machine learning #3 that reduces a difference between the estimated artificial spectrum #3 obtained by adding the estimated artificial spectrum #2 corresponding to the volume of interest based on the plurality of estimated artificial spectra #1 corresponding to the plurality of voxels output from the neural network #1 during learning and the estimated artificial baseline #2 corresponding to the volume of interest based on the plurality of artificial baselines #1 corresponding to the plurality of voxels output from the neural network #2 during learning and the measured spectrum #3. Here, a weighting factor for the artificial spectrum #2 and a weighting factor for the artificial baseline #2 are trained in machine learning #3. The training-in-progress neural network #1 is generated by machine learning #1 that reduces a difference between the estimated artificial spectrum #2 corresponding to the volume of interest based on the plurality of estimated artificial spectra #1 corresponding to the plurality of voxels output by the untrained neural network #1 and the measured spectrum #2 calculated by the mathematical model. The training-in-progress neural network #2 is generated by machine learning #2 that reduces a difference between the estimated artificial baseline #2 corresponding to the volume of interest based on the plurality of estimated artificial baselines #1 corresponding to the plurality of voxels output from the untrained neural network #2 and the measured baseline #2 obtained by subtracting the measured spectrum #2 from the measured spectrum #3.

FIG. 14 is a diagram schematically illustrating a first stage of the training processing of the trained model #1 and the trained model #2. The untrained neural network #1 is a neural network corresponding to the trained model #1 before execution of two-stage machine learning, and the untrained neural network #2 is a neural network corresponding to the trained model #2 before execution of two-stage machine learning.

The processing circuitry 51 acquires a plurality of training samples having different subjects and/or different collection conditions. Each training sample is a combination of the pixel value of the shimming map related to the volume of interest, the pixel value of the morphological image related to the volume of interest, and the metabolite concentration that can be included in the volume of interest. In addition, the processing circuitry 51 acquires a measured spectrum #2, a measured spectrum #3 (illustrated in FIG. 15), and a measured baseline #2 for each training sample. The measured spectrum #2 is correct data of an artificial spectrum that does not include the baseline component and is calculated by a mathematical model based on the metabolite concentration in the training sample. For example, the processing circuitry 51 calculates the measured spectrum #2 as the sum of the concentration component and the molecular component of the spectrum signal model Y(ν) illustrated in FIG. 4. The measured spectrum #3 is an observation spectrum obtained by performing spectrum collection such as MRS and NMR on the subject of the training sample. The measured baseline is the measured data of the baseline. The measured baseline is generated by subtracting the measured spectrum #2 from the measured spectrum #3.

First, the machine learning #1 will be described. For each training sample, the processing circuitry 51 inputs the pixel value of the shimming map related to the volume of interest and the metabolite concentration that can be included in the volume of interest to the untrained neural network #1, and estimates the artificial spectrum #1 (hereinafter, the estimated artificial spectrum #1) that corresponds to each of the plurality of voxels included in the volume of interest and does not include the baseline component. Next, the processing circuitry 51 adds and averages the plurality of estimated artificial spectra #1 corresponding to the plurality of voxels to generate an artificial spectrum #2 (hereinafter, an estimated artificial spectrum #2) corresponding to the volume of interest and not including the baseline component. The processing circuitry 51 calculates a loss between the estimated artificial spectrum #2 and the measured spectrum #2. As the loss, L1 loss and L2 loss can be used. The processing circuitry 51 updates the network parameters of the untrained neural network #1 in such a way as to reduce the calculated loss. The processing circuitry 51 repeats updating of the network parameters while changing the training samples until a predetermined end condition is satisfied. In a case where the end condition is satisfied, the network parameter in the number of updates is stored as the network parameter at the time of completion of the machine learning #1. The neural network to which the network parameter is assigned is used as a training-in-progress neural network #1 (illustrated in FIG. 15).

Next, the machine learning #2 will be described. For each training sample, the processing circuitry 51 inputs the pixel value of the shimming map related to the volume of interest and the pixel value of the morphological image related to the volume of interest to the untrained neural network #2, and estimates an artificial baseline #1 (hereinafter, estimated artificial baseline #1) corresponding to each of the plurality of voxels included in the volume of interest. Next, the processing circuitry 51 sums and averages the plurality of estimated artificial baselines #1 corresponding to the plurality of voxels to generate an artificial baseline #2 (hereinafter, estimated artificial baseline #2) corresponding to the volume of interest. The processing circuitry 51 calculates a loss between the estimated artificial baseline #2 and the measured baseline #2. As the loss, L1 loss and L2 loss can be used. The processing circuitry 51 updates the network parameters of the untrained neural network #2 in such a way as to reduce the calculated loss. The processing circuitry 51 repeats updating of the network parameters while changing the training samples until a predetermined end condition is satisfied. In a case where the end condition is satisfied, the network parameter in the number of updates is stored as the network parameter at the time of completion of the machine learning #2. The neural network to which the network parameter is assigned is used as a training-in-progress neural network #2 (illustrated in FIG. 15).

FIG. 15 is a diagram schematically illustrating a second stage of the training processing of the trained model #1 and the trained model #2. As illustrated in FIG. 15, for each training sample, the processing circuitry 51 inputs the pixel value of the shimming map related to the volume of interest and the metabolite concentration that can be included in the volume of interest to the training-in-progress neural network #1, and estimates a plurality of estimated artificial spectra #1 corresponding to a plurality of voxels. Next, the processing circuitry 51 adds and averages the plurality of estimated artificial spectra #1 to generate an estimated artificial spectrum #2 corresponding to the volume of interest. In addition, for each training sample, the processing circuitry 51 inputs the pixel value of the shimming map related to the volume of interest and the pixel value of the morphological image to the training-in-progress neural network #2, and estimates a plurality of estimated artificial baselines #1 corresponding to a plurality of voxels. The processing circuitry 51 then averages the plurality of estimated artificial baselines #1 to generate an estimated artificial baseline #2 corresponding to the volume of interest.

Next, the processing circuitry 51 multiplies the estimated artificial spectrum #2 by a weighting factor α, multiplies the estimated artificial baseline #2 by a weighting factor β, and adds the estimated artificial spectrum #2 with the weighting factor α and the estimated artificial baseline #2 with the weighting factor β to generate the estimated artificial spectrum #3 related to the volume of interest. The processing circuitry 51 calculates a loss between the estimated artificial spectrum #3 and the measured spectrum #3. As the loss, L1 loss and L2 loss can be used. The processing circuitry 51 updates the network parameter #1 of the training-in-progress neural network #1 and the network parameter #2, the weighting coefficient α, and/or the weighting coefficient β of the training-in-progress neural network #2 in such a way as to reduce the calculated loss. The processing circuitry 51 repeats the update processing while changing the training sample until a predetermined end condition is satisfied. In a case where the end condition is satisfied, the network parameter #1, the network parameter #2, the weighting coefficient α, and/or the weighting coefficient β in the number of update times are stored as the network parameter #1, the network parameter #2, the weighting coefficient α, and/or the weighting coefficient β at the time of completion of the machine learning #3. The neural network to which the network parameter #1 is assigned is used as the trained model #1, and the neural network to which the network parameter #2 is assigned is used as the trained model #2.

As described above, the training processing of the trained model #1 and the trained model #2 ends.

As described above, according to the fifth specific example, the artificial spectrum regarding the volume of interest can be estimated from the combination of the pixel value of the shimming map regarding the volume of interest, the pixel value of the morphological image, and the metabolite concentration by using the neural network. This makes it possible to obtain the artificial spectrum of the volume of interest with light computational load and high accuracy.

### Sixth Specific Example

A sixth specific example is a modification of the fifth specific example. A spectrum generation apparatus 50 according to the sixth specific example generates the artificial spectrum of the volume of interest from the morphological correlation parameter value for each pixel value via the spectrum generation parameter value for each voxel while using the trained model. As a result, since the spectrum generation parameter value for each voxel is passed, it is expected that the accuracy of the artificial spectrum is improved as compared with the fifth specific example.

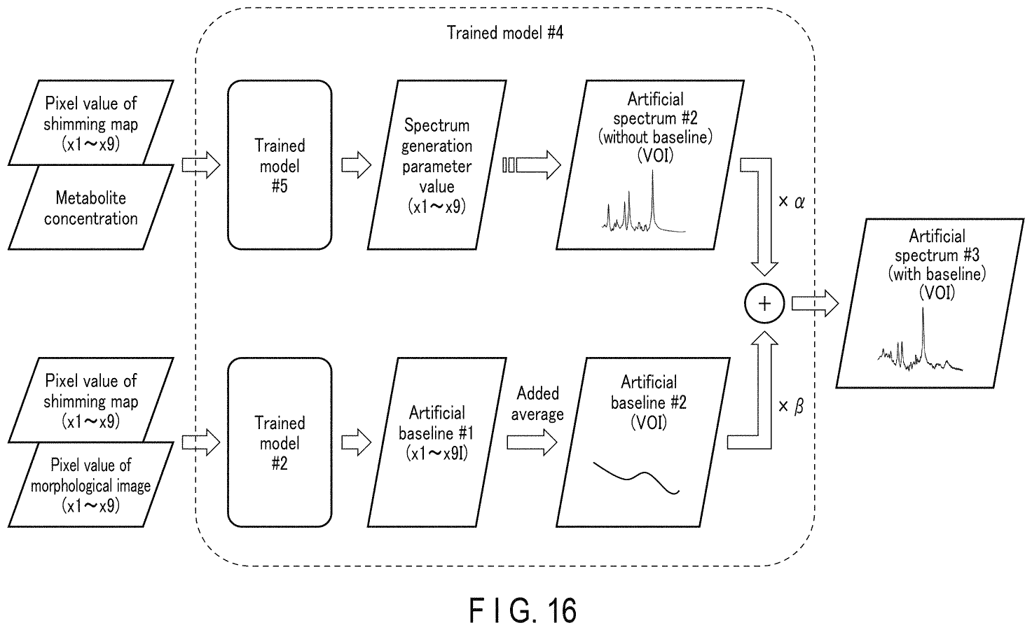

FIG. 16 is a diagram illustrating an input/output relationship of a trained model according to the sixth specific example. Note that, in FIG. 16, the volume of interest VOI is assumed to be, as an example, a rectangular region including nine pixels x1 to x9. Note that the volume of interest VOI according to the sixth specific example can be applied to any size and shape.

As illustrated in FIG. 16, the processing circuitry 51 acquires the morphological image and the shimming map regarding the imaging region including the volume of interest of the subject by the acquisition function 512. In addition, the processing circuitry 51 acquires the concentration of metabolites (metabolite concentration) that can be included in the volume of interest by the acquisition function 512. The morphological image, the shimming map, and the metabolite concentration are the same as those in the fifth specific example.

By the estimation function 513, the processing circuitry 51 applies the parameter value of the shimming map and the metabolite concentration that can be included in the volume of interest to the trained model #5 for each of the plurality of voxels included in the volume of interest to estimate the parameter value of the spectrum generation parameter (spectrum generation parameter value). The trained model #5 is a neural network trained to input the parameter value of the shimming map for each voxel and the metabolite concentration that can be included in the volume of interest and output the spectrum generation parameter value for each voxel.

By means of the artificial spectrum generation function 514, the processing circuitry 51 generates an artificial spectrum #1 for the volume of interest based on the spectrum generation parameter value of each of the plurality of voxels. For example, as illustrated in FIG. 3, the processing circuitry 51 applies the spectrum generation parameter value to the spectrum signal model for each of the plurality of voxels to generate the artificial spectrum not including the baseline component, and adds the artificial spectra over the plurality of voxels configuring the volume of interest to generate the artificial spectrum #2 related to the volume of interest and not including the baseline component.

On the other hand, the processing circuitry 51 applies the parameter value of the shimming map and the parameter value of the morphological image related to the volume of interest to the trained model #2 by the artificial spectrum generation function 514 to generate a plurality of artificial baselines #1 corresponding to a plurality of voxels, and generates an artificial baseline #2 related to the volume of interest by averaging the plurality of artificial baselines #1. The generation processing is similar to the artificial baseline generation processing according to the fifth specific example.

Then, the processing circuitry 51 adds the artificial spectrum #2 and the artificial baseline #2 by the artificial spectrum generation function 514 to generate the artificial spectrum #3. Specifically, the processing circuitry 51 performs weighted addition of the artificial spectrum #2 and the artificial baseline #2 to generate the artificial spectrum #2. As an example, the processing circuitry 51 multiplies the artificial spectrum #2 by the weighting coefficient α, multiplies the artificial baseline #2 by the weighting coefficient β, and adds the artificial spectrum #2 with the weighting coefficient α and the artificial baseline #2 with the weighting coefficient β to generate the artificial spectrum #3.

Note that the trained model #5 and the trained model #2 are trained in advance and stored in the memory 53 or the like. The trained model #5 and the trained model #2 may be managed as individual machine training-in-Progress models, or the trained model #5, the trained model #2, and the adder may be collectively managed as one trained model #4. Note that the adder means a network layer that adds the artificial spectrum #2 and the artificial baseline #2.

### (Modification 1)

It is assumed that the spectrum generation apparatus according to the above embodiment is incorporated in the magnetic resonance imaging apparatus 1. However, the spectrum generation apparatus according to the present embodiment is not necessarily incorporated in the magnetic resonance imaging apparatus 1 as long as an artificial spectrum simulating a spectrum that can be collected by the magnetic resonance imaging apparatus 1 can be generated from the morphological correlation parameter value. Hereinafter, a spectrum generation apparatus according to Modification 1 will be described. Note that, in the following description, components having substantially the same functions as those of the above embodiment will be denoted by the same reference numerals, and redundant description will be given only when necessary.

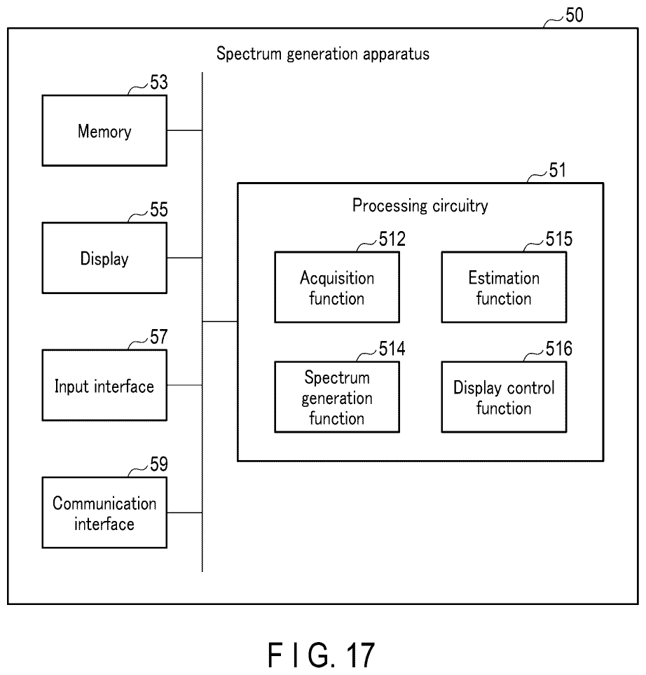

FIG. 17 is a diagram illustrating a configuration example of a spectrum generation apparatus 50 according to Modification 1. The spectrum generation apparatus 50 illustrated in FIG. 17 is a computer separate from the magnetic resonance imaging apparatus 1 illustrated in FIG. 1. As illustrated in FIG. 17, an acquisition function 512, an estimation function 513, an artificial spectrum generation function 514, a training function 515, and a display control function 516 are realized by executing various programs.

By means of the acquisition function 512, the processing circuitry 51 acquires, for each of the plurality of voxels included in the volume of interest, parameter values of one or more morphological correlation parameters correlated to a morphology in the volume of interest. The morphology correlation parameter includes a morphological image representing a morphology within the volume of interest and/or a label for an anatomical site corresponding to the morphology within the volume of interest. The morphological image includes a collected image collected by a medical image diagnostic apparatus or an optical camera, a segmentation image obtained by performing segmentation processing on the collected image, and/or a quantitative value map generated based on the collected image. The collected image only needs to represent the morphology within the volume of interest, and therefore is not limited to the MRI image collected by the magnetic resonance imaging apparatus, but may be an X-ray CT image collected by the X-ray computed tomography apparatus, an ultrasonic image collected by the ultrasonic diagnostic apparatus, or a nuclear medicine image collected by the nuclear medicine diagnosis apparatus.

By means of the estimation function 513, the processing circuitry 51 estimates a plurality of parameter sets corresponding to a plurality of voxels based on the parameter values of the morphological correlation parameters acquired by the acquisition function 512. Each of the plurality of parameter sets includes a parameter value of one or more kinds of spectrum generation parameters.

By the artificial spectrum generation function 514, the processing circuitry 51 applies the plurality of parameter sets estimated by the estimation function 513 to the basis spectrum to generate a plurality of first artificial spectra corresponding to the plurality of voxels included in the volume of interest. Then, the processing circuitry 51 generates a second artificial spectrum corresponding to the volume of interest based on the plurality of first artificial spectra. The second artificial spectrum can be used for any machine learning training sample. According to the present embodiment, since it is not necessary to actually perform spectrum collection on the subject, it is possible to generate the second artificial spectrum as the training sample inexpensively and in large quantities. Also in Modification 1, similarly to the above embodiment, a spectrum may be generated to confirm a spectrum expected to be collected before spectrum collection by the magnetic resonance imaging apparatus.

With the training function 515, the processing circuitry 51 trains the untrained neural network based on the plurality of training samples to generate a parameter estimation model to be used in the estimation function 513.

By the display control function 516, the processing circuitry 51 displays various types of information on the display 55. For example, the processing circuitry 51 displays the second artificial spectrum generated by the artificial spectrum generation function 514 on the display 55.

### (Modification 2)

In some embodiments above, it was assumed that the spectrum is an MRS spectrum. However, the present embodiment is not limited thereto. As the spectrum according to Modification 2, a difference spectrum collected by editing MRS imaging is used. Editing MRS imaging is a spectral acquisition method that performs two pulse sequences with different frequency-specific frequency selective pulses and collects the difference spectra of the two resulting spectra. As a pulse sequence of editing MRS imaging, for example, MEGA-PRESS is known. Similarly to the present embodiment, the first artificial spectrum and the second artificial spectrum of the difference spectrum can also be generated and displayed, for example, according to the processing example illustrated in FIG. 2. Therefore, according to Modification 2, it is possible to generate an artificial difference spectrum with high accuracy.

### (Modification 3)

In some embodiments above, it was assumed that the spectrum is an MRS spectrum. However, the present embodiment is not limited thereto. As the spectrum according to Modification 3, a chemical exchange saturation transfer (CEST) spectrum collected by CEST imaging is used. The first artificial spectrum and the second artificial spectrum of the CEST spectrum can also be generated and displayed, for example, according to the processing example illustrated in FIG. 2, similarly to the present embodiment. Therefore, according to Modification 3, it is possible to generate an artificial CEST spectrum with high accuracy.

According to some embodiments described above, the spectrum generation apparatus 50 according to the present embodiment includes a processing circuitry 51. The processing circuitry 51 obtains, for each of the plurality of voxels included in the volume of interest, parameter values of one or more morphological correlation parameters that correlate to morphology within the volume of interest. The processing circuitry 51 estimates a parameter value of one or more kinds of spectrum generation parameters based on the parameter value of the morphological correlation parameter for each of the plurality of voxels. The processing circuitry 51 applies the parameter values of the one or more kinds of spectrum generation parameters of each of the plurality of voxels to the basis spectrum to generate a plurality of first artificial spectra corresponding to the plurality of voxels, and generates a second artificial spectrum corresponding to the volume of interest based on the plurality of first artificial spectra.

According to the above configuration, the processing circuitry 51 generates the second artificial spectrum corresponding to the volume of interest by approximately reproducing a process of generating an actually measured spectrum by MRS imaging in which an MR signal obtained by summing MR signal components emitted from various metabolites included in the volume of interest is subjected to frequency analysis or the like to generate an actually measured spectrum. As described above, since the processing circuitry 51 can generate the average spectrum in the volume of interest as the second artificial spectrum, it is possible to generate the artificial spectrum close to the actually collected spectrum as compared with the comparative example in which the artificial spectrum is generated by complex simulation for each voxel.

According to at least one embodiment described above, the accuracy of the artificial spectrum can be improved.

The term “processor” used in the above description means, for example, a CPU, a GPU, or a circuit such as an application specific integrated circuit (ASIC) or a programmable logic device (for example, a simple programmable logic device (SPLD), a complex programmable logic device (CPLD), and a field programmable gate array (FPGA)). The processor realizes a function by reading and executing a program stored in the storage circuit. Instead of storing the program in the storage circuit, the program may be directly incorporated in the circuit of the processor. In this case, the processor realizes the function by reading and executing a program incorporated in the circuit. On the other hand, in a case where the processor is, for example, an ASIC, the function is directly incorporated as a logic circuit in a circuit of the processor instead of storing the program in the storage circuit. Note that each processor of the present embodiment is not limited to a case where each processor is configured as a single circuit, and a plurality of independent circuits may be combined and configured as one processor to realize the function. Furthermore, a plurality of components in FIGS. 1 and 17 may be integrated into one processor to realize the function.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Regarding the above embodiments, the following supplementary notes are disclosed as one aspect and selective features of the invention.

### (Supplementary Note 1)

A spectrum generation apparatus including:
an acquisition unit that acquires, for each of a plurality of voxels included in a volume of interest, a parameter value of one or more kinds of morphological correlation parameters correlated to a morphology in the volume of interest;
an estimation unit that estimates, for each of the plurality of voxels, a parameter value of one or more spectrum generation parameters based on the parameter value of the morphological correlation parameter; and
a generation unit that applies the parameter value of the one or more kinds of spectrum generation parameters of each of the plurality of voxels to a basis spectrum to generate a plurality of first artificial spectra corresponding to the plurality of voxels and generate a second artificial spectrum corresponding to the volume of interest based on the plurality of first artificial spectra.

### (Supplementary Note 2)

The spectrum generation apparatus according to Supplementary Note 1, in which the morphological correlation parameter includes a morphological image representative of a morphology within the volume of interest and/or a label for an anatomical site corresponding to a morphology within the volume of interest.

### (Supplementary Note 3)

The spectrum generation apparatus according to Supplementary Note 2, in which the morphological image includes a collected image collected by a medical image diagnostic apparatus or an optical camera, a segmentation image obtained by performing segmentation processing on the collected image, and/or a quantitative value map generated based on the collected image.

### (Supplementary Note 4)

The spectrum generation apparatus according to Supplementary Note 3, in which the collected image includes an MRI image collected by main imaging of a magnetic resonance imaging apparatus and/or shimming data collected by calibration imaging of a magnetic resonance imaging apparatus.

### (Supplementary Note 5)

The spectrum generation apparatus according to Supplementary Note 3, in which the morphological image is an image collected with a spatial resolution corresponding to the plurality of voxels higher than a spatial resolution corresponding to the volume of interest.

### (Supplementary Note 6)

The spectrum generation apparatus according to Supplementary Note 1, in which
the acquisition unit further acquires an measured spectrum of the volume of interest collected by the magnetic resonance imaging apparatus, and
the estimation unit estimates the parameter value of the one or more types of spectrum generation parameters based on the parameter value of the morphological correlation parameter and the measured spectrum.

### (Supplementary Note 7)

The spectrum generation apparatus according to Supplementary Note 6, in which the measured spectrum includes an MRS spectrum, a difference spectrum, and/or a CEST spectrum.

### (Supplementary Note 8)

The spectrum generation apparatus according to Supplementary Note 1, in which the estimation unit applies the parameter value of the morphological correlation parameter to a trained model or a random number generator to estimate the parameter value of the one or more kinds of spectrum generation parameters.

### (Supplementary Note 9)

The spectrum generation apparatus according to Supplementary Note 1, in which
the generation unit generates the plurality of first artificial spectra by applying the parameter value of the spectrum generation parameter of each of the plurality of voxels to a spectrum signal model, and
the spectrum signal model is a mathematical model representing the basis spectrum with the spectrum generation parameter.

### (Supplementary Note 10)

The spectrum generation apparatus according to Supplementary Note 9, in which the spectrum generation parameter includes a baseline with respect to the basis spectrum, a phase shift with respect to the basis spectrum, a concentration of a metabolite represented by the basis spectrum, a half-value width of the basis spectrum, and/or a frequency shift with respect to the basis spectrum.

### (Supplementary Note 11)

The spectrum generation apparatus according to Supplementary Note 1, in which the generation unit generates the second artificial spectrum for each of a plurality of metabolites included in the volume of interest.

### (Supplementary Note 12)

The spectrum generation apparatus according to Supplementary Note 11, in which the generation unit generates a summation spectrum obtained by adding the second artificial spectrum for each of the plurality of metabolites in addition to the second artificial spectrum for each of the plurality of metabolites.

### (Supplementary Note 13)

The spectrum generation apparatus according to Supplementary Note 12, further including
a display control unit that displays a morphological image related to the volume of interest and the second artificial spectrum for each of the plurality of metabolites,
in which the display control unit superimposes a mark representing the volume of interest on the morphological image and arranges the second artificial spectrum for each of the plurality of metabolites around the morphological image.

### (Supplementary Note 14)

The spectrum generation apparatus according to Supplementary Note 1, further including a display control unit that displays the second artificial spectrum on a display device.

### (Supplementary Note 15)

The spectrum generation apparatus according to Supplementary Note 14, in which the display control unit displays the second artificial spectrum side by side in a morphological image related to the volume of interest.

### (Supplementary Note 16)

The spectrum generation apparatus according to Supplementary Note 1, in which
the morphological correlation parameter includes a shimming map and a morphological image, and
the generation unit
applies a parameter value of the shimming map corresponding to the volume of interest and a parameter value of the one or more kinds of spectrum generation parameters to a first trained model to generate a third artificial spectrum for the volume of interest;
applies a parameter value of the shimming map and a parameter value of the morphological image for the volume of interest to a second trained model to generate an artificial baseline for the volume of interest; and
adds the third artificial spectrum and the artificial baseline to generate the second artificial spectrum.

### (Supplementary Note 17)

A magnetic resonance imaging apparatus including:
a collection unit configured to perform MR imaging on a volume of interest set on a subject to collect parameter values of one or more kinds of morphological correlation parameters correlated with a morphology in the volume of interest for each of a plurality of voxels included in the volume of interest;
an estimation unit configured to estimate, for each of the plurality of voxels, a parameter value of one or more kinds of spectrum generation parameters based on the parameter value of the morphological correlation parameter; and
a generation unit configured to apply a parameter value of the one or more kinds of spectrum generation parameters of each of the plurality of voxels to a basis spectrum to generate a plurality of first artificial spectra corresponding to the plurality of voxels and to generate a second artificial spectrum corresponding to the volume of interest based on the plurality of first artificial spectra.

### (Supplementary Note 18)

A spectrum generation method causing a computer to execute:
acquiring, for each of a plurality of voxels included in a volume of interest, a parameter value of one or more kinds of morphological correlation parameters correlated to a morphology in the volume of interest;
estimating, for each of the plurality of voxels, a parameter value of one or more spectrum generation parameters based on the parameter value of the morphological correlation parameter; and
applying the parameter value of the one or more spectrum generation parameters of each of the plurality of voxels to a basis spectrum to generate a plurality of first artificial spectra corresponding to the plurality of voxels and generate a second artificial spectrum corresponding to the volume of interest based on the plurality of first artificial spectra.

### (Supplementary Note 19)

A spectrum generation apparatus including:
an acquisition unit that acquires a morphological image and a shimming map regarding an imaging region including a volume of interest of a subject;
an acquisition unit that acquires a concentration of a metabolite that can be included in the volume of interest; and
a generation unit that generates a plurality of artificial spectra #1 corresponding to a plurality of voxels included in the volume of interest by applying a parameter value of the shimming map related to the volume of interest and a concentration of the metabolite that can be included in the volume of interest to a trained model #1, generates a second artificial spectrum #2 corresponding to the volume of interest based on the plurality of first artificial spectra #1, generates a plurality of artificial baselines #1 corresponding to the plurality of voxels by applying a parameter value of the shimming map related to the volume of interest and a parameter value of the morphological image to a trained model #2, generates a second artificial baseline #2 corresponding to the volume of interest based on the plurality of first artificial baselines #1, and adds the artificial spectrum #2 and the artificial baseline #2 to generate an artificial spectrum #3.

### (Supplementary Note 20)

A spectrum generation apparatus including:
an acquisition unit that acquires a morphological image and a shimming map regarding an imaging region including a volume of interest of a subject;
an acquisition unit that acquires a concentration of a metabolite that can be included in the volume of interest; and
a generation unit that estimates a parameter value of a spectrum generation parameter for each of a plurality of voxels included in the volume of interest by applying a parameter value of the shimming map and a concentration of the metabolite that can be included in the volume of interest to a trained model #5,
generates an artificial spectrum #1 of each of the plurality of voxels based on a parameter value of the spectrum generation parameter of each of the plurality of voxels, and generates an artificial spectrum #2 for the volume of interest based on the artificial spectrum #1 of each of the plurality of voxels,
applies the parameter value of the shimming map and the parameter values of the morphological image for the volume of interest to a trained model #2 to generate a plurality of artificial baselines #1 corresponding to the plurality of voxels, and generate an artificial baseline #2 for the volume of interest based on the plurality of baselines #1, and
adds the artificial spectrum #2 and the artificial baseline #2 to generate an artificial spectrum #3.

### (Supplementary Note 21)

The spectrum generation apparatus according to Supplementary Note 20, in which the generation unit generates the artificial spectrum #3 by performing weighted addition of the artificial spectrum #2 and the artificial baseline #2.

### (Supplementary Note 22)

The spectrum generation apparatus according to Supplementary Note 20, in which the trained model #1 and the trained model #2 are generated by machine learning #3 that reduces a difference between an estimated artificial spectrum #3 obtained by adding an estimated artificial spectrum #2 based on a plurality of estimated artificial spectra #1 output by the training-in-progress neural network #1 and an estimated artificial baseline #2 based on a plurality of estimated artificial baselines #1 output by the training-in-progress neural network #2 and a measured spectrum #3.

### (Supplementary Note 23)

The spectrum generation apparatus according to Supplementary Note 22, in which the training-in-progress neural network #1 is generated by machine learning #1 that reduces a difference between an estimated artificial spectrum #2 based on a plurality of estimated artificial spectra #1 output by the untrained neural network #1 and a measured spectrum #2 calculated by a mathematical model.

### (Supplementary Note 24)

The spectrum generation apparatus according to Supplementary Note 22, in which the training-in-progress neural network #2 is generated by machine learning #2 that reduces a difference between an estimated artificial baseline #2 based on a plurality of estimated artificial baselines #1 output by the untrained neural network #2 and a measured baseline #2 obtained by subtracting the measured spectrum #2 from the measured spectrum #3.

### (Supplementary Note 25)

The spectrum generation apparatus according to Supplementary Note 21, in which a weighting coefficient α for the artificial spectrum #2 and a weighting coefficient β for the artificial baseline #2 are trained in machine learning #3.

### (Supplementary Note 26)

A spectrum generation apparatus including:
an acquisition unit that acquires a morphological image and a shimming map regarding an imaging region including a volume of interest of a subject;
an acquisition unit that acquires a concentration of a metabolite that can be included in the volume of interest; and
a generation unit that applies a parameter value of the shimming map related to the volume of interest, a parameter value of the morphological image related to the volume of interest, and a concentration of the metabolite that can be included in the volume of interest to a trained model #0 to generate an artificial spectrum #2 related to the volume of interest.

What is claimed is:

1. A spectrum generation apparatus comprising a processing circuitry executing:
acquiring, for each of a plurality of voxels included in a volume of interest, a parameter value of one or more kinds of morphological correlation parameters correlated to a morphology in the volume of interest;
estimating, for each of the voxels, a parameter value of one or more spectrum generation parameters based on the parameter value of the morphological correlation parameter; and
applying the parameter value of the one or more spectrum generation parameters of each of the voxels to a basis spectrum to generate a plurality of first artificial spectra corresponding to the voxels and generate a second artificial spectrum corresponding to the volume of interest based on the first artificial spectra.

2. The spectrum generation apparatus according to claim 1, wherein the morphological correlation parameter comprises a morphological image representative of a morphology within the volume of interest and/or a label for an anatomical site corresponding to a morphology within the volume of interest.

3. The spectrum generation apparatus according to claim 2, wherein the morphological image comprises a collected image collected by a medical image diagnostic apparatus or an optical camera, a segmentation image obtained by performing segmentation processing on the collected image, and/or a quantitative value map generated based on the collected image.

4. The spectrum generation apparatus according to claim 3, wherein the collected image comprises an MRI image collected by main imaging of a magnetic resonance imaging apparatus and/or shimming data collected by calibration imaging of a magnetic resonance imaging apparatus.

5. The spectrum generation apparatus according to claim 3, wherein the morphological image is an image collected with a spatial resolution corresponding to the voxels higher than a spatial resolution corresponding to the volume of interest.

6. The spectrum generation apparatus according to claim 1, wherein
the processing circuitry further executes:
acquiring a measured spectrum of the volume of interest collected by the magnetic resonance imaging apparatus; and
estimating the parameter value of the one or more types of spectrum generation parameters based on the parameter value of the morphological correlation parameter and the measured spectrum.

7. The spectrum generation apparatus according to claim 6, wherein the measured spectrum includes an MRS spectrum, a difference spectrum, and/or a CEST spectrum.

8. The spectrum generation apparatus according to claim 1, wherein the processing circuitry applies the parameter value of the morphological correlation parameter to a trained model or a random number generator to estimate the parameter value of the one or more kinds of spectrum generation parameters.

9. The spectrum generation apparatus according to claim 1, wherein
the processing circuitry generates the first artificial spectra by applying the parameter value of the spectrum generation parameter of each of the voxels to a spectrum signal model, and
the spectrum signal model is a mathematical model representing the basis spectrum with the spectrum generation parameter.

10. The spectrum generation apparatus according to claim 9, wherein the spectrum generation parameter includes a baseline with respect to the basis spectrum, a phase shift with respect to the basis spectrum, a concentration of a metabolite represented by the basis spectrum, a half-value width of the basis spectrum, and/or a frequency shift with respect to the basis spectrum.

11. The spectrum generation apparatus according to claim 1, wherein the processing circuitry generates the second artificial spectrum for each of a plurality of metabolites included in the volume of interest.

12. The spectrum generation apparatus according to claim 11, wherein the processing circuitry generates a summation spectrum obtained by adding the second artificial spectrum for each of the metabolites in addition to the second artificial spectrum for each of the metabolites.

13. The spectrum generation apparatus according to claim 12, further comprising
a display control unit that displays a morphological image related to the volume of interest and the second artificial spectrum for each of the metabolites,
wherein the processing circuitry superimposes a mark representing the volume of interest on the morphological image and arranges the second artificial spectrum for each of the metabolites around the morphological image.

14. The spectrum generation apparatus according to claim 1, wherein the processing circuitry displays the second artificial spectrum on a display device.

15. The spectrum generation apparatus according to claim 14, wherein the processing circuitry displays the second artificial spectrum side by side in a morphological image related to the volume of interest.

16. The spectrum generation apparatus according to claim 1,
wherein the morphological correlation parameter includes a shimming map and a morphological image, and
the processing circuitry
applies a parameter value of the shimming map corresponding to the volume of interest and a parameter value of the one or more kinds of spectrum generation parameters to a first trained model to generate a third artificial spectrum for the volume of interest;
applies a parameter value of the shimming map and a parameter value of the morphological image for the volume of interest to a second trained model to generate an artificial baseline for the volume of interest; and
adds the third artificial spectrum and the artificial baseline to generate the second artificial spectrum.

17. A magnetic resonance imaging apparatus comprising:
a sequence control circuitry configured to perform MR imaging on a volume of interest set on a subject to collect parameter values of one or more kinds of morphological correlation parameters correlated with a morphology in the volume of interest for each of a plurality of voxels included in the volume of interest; and
a processing circuitry configured to estimate, for each of the voxels, a parameter value of one or more kinds of spectrum generation parameters based on the parameter value of the morphological correlation parameter, and
apply a parameter value of the one or more kinds of spectrum generation parameters of each of the voxels to a basis spectrum to generate a plurality of first artificial spectra corresponding to the voxels and to generate a second artificial spectrum corresponding to the volume of interest based on the first artificial spectra.

18. A spectrum generation method causing a computer to execute:
acquiring, for each of a plurality of voxels included in a volume of interest, a parameter value of one or more kinds of morphological correlation parameters correlated to a morphology in the volume of interest;
estimating, for each of the plurality of voxels, a parameter value of one or more spectrum generation parameters based on the parameter value of the morphological correlation parameter; and
applying the parameter value of the one or more spectrum generation parameters of each of the plurality of voxels to a basis spectrum to generate a plurality of first artificial spectra corresponding to the plurality of voxels and generate a second artificial spectrum corresponding to the volume of interest based on the plurality of first artificial spectra.
